(19) United States
(12) Patent Application Publication
(10) Pub. No.: US 2024/0049521 A1
(43) Pub. Date: Feb. 8, 2024

(54) DISPLAY PANEL AND METHOD FOR MANUFACTURING SAME

(71) Applicant: WUHAN CHINA STAR OPTOELECTRONICS SEMICONDUCTOR DISPLAY TECHNOLOGY CO., LTD., Wuhan, Hubei (CN)

(72) Inventors: Cheng YANG, Wuhan, Hubei (CN); Pan JIANG, Wuhan, Hubei (CN)

(21) Appl. No.: 17/605,497

(22) PCT Filed: Aug. 30, 2021
(86) PCT No.: PCT/CN2021/115284

§ 371 Date: Oct. 21, 2021

(30) Foreign Application Priority Data
Aug. 5, 2021 (CN) 202110897314.6

(51) Int. Cl. H10K 59/124; H10K 59/12; H10K 59/88

(52) U.S. Cl. CPC H10K 59/124; H10K 59/1201; H10K 59/88

(57) ABSTRACT

A display panel and a preparation method thereof are provided. A first display region and a second display region are defined on the display panel, and the display panel includes: a substrate, a driving device layer, and a light-emitting device layer. In the second display region, the driving device layer is further provided with a dummy through hole located within an orthographic projection range of at least one of the light-emitting subpixels on the substrate, and the dummy through hole and the at least one light-emitting subpixel are insulated from each other. The display panel can ensure the electrical uniformity between thin film transistors (TFTs) in the second display region, thereby alleviating non-uniform display.

This application claims priority to Chinese Patent Application No. 202110897314.6, filed with the China National Intellectual Property Administration on Aug. 5, 2021 and entitled “DISPLAY PANEL AND METHOD FOR MANUFACTURING SAME”, which is incorporated herein by reference in its entirety.

### FIELD OF INVENTION

The present disclosure relates to display technologies, and more particularly, to a display panel and a method for manufacturing a display panel.

### BACKGROUND OF INVENTION

In recent years, smartphones have entered a “full-screen” era, and the pursuit of an ultimate high screen-to-body ratio has become a new development trend. Therefore, a camera under panel (CUP) technology emerges. In the CUP technology, a camera is disposed below a screen, and this region is referred to as a CUP region. This technology can provide a CUP function while achieving full-screen display, and is an ultimate solution for full screen phones.

In a screen using the CUP technology, the display region may be divided into a CUP region and a normal display region. The two regions have different structural designs and pixel designs. However, in the conventional technologies, because the CUP region and the normal display region have different structural designs, the two regions have different circuit traces and processes, and further electrical properties of a driving device located in the CUP region are different from those of the normal display region. As a result, non-uniform display occurs in the CUP region.

Therefore, there is an urgent need to improve the electrical properties of the driving device in the CUP region, to improve the electrical uniformity between the CUP region and the normal display region, thereby alleviating the non-uniform display.

### SUMMARY OF INVENTION

In the conventional technologies, because the CUP region and the normal display region have different structural designs, the two regions have different circuit traces and processes, and further electrical properties of a driving device located in the CUP region are different from those of the normal display region. As a result, non-uniform display occurs in the CUP region.

An objective of the present disclosure is to provide a display panel and a preparation method thereof, to resolve a technical problem in the prior art of non-uniform display in a camera under panel (CUP) region because electrical properties of a driving device located in the CUP region are different from those of a normal display region.

To resolve the above problem, the present disclosure provides a display panel, wherein a first display region and a second display region are defined on the display panel, and the display panel includes: a substrate; a driving device layer, disposed on the substrate and including a plurality of thin film transistors (TFTs); and a light-emitting device layer, disposed on the driving device layer and including a plurality of light-emitting subpixels arranged in an array.
wherein in the second display region, the driving device layer is further provided with a dummy through hole located within an orthographic projection range of at least one of the light-emitting subpixels on the substrate, and the dummy through hole and the at least one light-emitting subpixel are insulated from each other.

In some embodiments, in the second display region, the TFT is disposed at an edge of the second display region close to the first display region.

In some embodiments, the TFT is disposed at a same layer with the dummy through hole.

In some embodiments, the TFT includes: an active layer, disposed on the substrate; a first insulating layer, covering the active layer; a first metal layer, disposed on the first insulating layer; a second insulating layer, disposed on the first metal layer; and a second metal layer, disposed on the second insulating layer and patterned to form a source and a drain, wherein the source and the drain are electrically connected to the active layer respectively through a first through hole and a second through hole that runs through the first insulating layer and the second insulating layer,
wherein the dummy through hole is disposed at a same layer with the first through hole and the second through hole.

In some embodiments, a quantity of the dummy through holes located within the orthographic projection range of the at least one light-emitting subpixel on the substrate is greater than or equal to 1.

In some embodiments, a shape of the dummy through hole includes at least one of a rectangle or a circle.

In some embodiments, the light-emitting subpixels have different sizes, and the quantity of dummy through holes is proportional to the sizes of the light-emitting subpixels.

In some embodiments, in the first display region, the driving device layer is provided with a plurality of through holes corresponding to the light-emitting subpixels, and the through holes are electrically connected to the light-emitting subpixels,
wherein a density of the dummy through holes in the second display region is equal to a density of the through holes in the first display region.

In some embodiments, the display panel further includes an organic planarization layer, wherein the organic planarization layer is disposed between the driving device layer and the light-emitting device layer, and the organic planarization layer fills the dummy through hole that runs through the first insulating layer and the second insulating layer.

The present disclosure further provides a method for manufacturing a display panel, wherein a first display region and a second display region are defined on the display panel, and the preparation method includes steps of:
providing a substrate; forming a driving device layer on the substrate, wherein the driving device layer includes a plurality of TFTs; and forming a light-emitting device layer on the driving device layer, wherein the light-emitting device layer includes a plurality of light-emitting subpixels arranged in an array,
wherein in the second display region, the driving device layer is further provided with a dummy through hole located within an orthographic projection range of each of the light-emitting subpixels on the substrate, and the dummy through hole and the light-emitting subpixels are insulated from each other.

The present disclosure further provides a method for manufacturing a display panel, wherein a first display region and a second display region are defined on the display panel, and the preparation method includes steps of:
providing a substrate; forming a driving device layer on the substrate, wherein the driving device layer includes a plurality of thin film transistors (TFTs); and forming a light-emitting device layer on the driving device layer, wherein the light-emitting device layer includes a plurality of light-emitting subpixels arranged in an array,
wherein in the second display region, the driving device layer is further provided with a dummy through hole located within an orthographic projection range of at least one of the light-emitting subpixels on the substrate, and the dummy through hole and the at least one light-emitting subpixel are insulated from each other.

In some embodiments, in the second display region, the TFT is disposed at an edge of the second display region close to the first display region.

In some embodiments, the TFT is disposed at a same layer with the dummy through hole.

In some embodiments, the step of forming the driving device layer on the substrate includes: sequentially disposing an active layer, a first insulating layer, a first metal layer, a second insulating layer, and a second metal layer on the substrate, wherein the second metal layer is patterned to form a source and a drain; and providing a first through hole and a second through hole that run through the first insulating layer and the second insulating layer and the dummy through hole located in the second display region,
wherein the source and the drain are electrically connected to the active layer respectively through the first through hole and the second through hole.

In some embodiments, the step of forming the driving device layer on the substrate further includes: forming an organic planarization layer on the second metal layer.

In some embodiments, a quantity of the dummy through holes located within the orthographic projection range of the at least one light-emitting subpixel on the substrate is greater than or equal to 1.

In some embodiments, the light-emitting subpixels have different sizes, and the quantity of dummy through holes is proportional to the sizes of the light-emitting subpixels.

In some embodiments, in the first display region, the driving device layer is provided with a plurality of through holes corresponding to the light-emitting subpixels, and the through holes are electrically connected to the light-emitting subpixels,
wherein a density of the dummy through holes in the second display region is equal to a density of the through holes in the first display region.

In some embodiments, the organic planarization layer fills the dummy through hole that runs through the first insulating layer and the second insulating layer.

In some embodiments, the dummy through hole is filled with a non-conductive material.

In the display panel and the preparation method thereof in the present disclosure, a dummy through hole located within an orthographic projection range of at least one of the light-emitting subpixels on the substrate is disposed in the second display region, and the dummy through hole and the at least one light-emitting subpixel are insulated from each other.

Provided with the dummy through hole, the driving device layer may also have a uniform hole-opening density in the second display region, to uniformly remove impurity elements, such as hydrogen in an annealing process, and the electrical uniformity between the TFTs in the second display region is ensured, thereby alleviating non-uniform display.

### BRIEF DESCRIPTION OF DRAWINGS

To describe the technical solutions in the embodiments of the present disclosure more clearly, the following briefly introduces the accompanying drawings required for describing the embodiments. Apparently, the accompanying drawings in the following description show only some embodiments of the present disclosure, and a person skilled in the art may still derive other accompanying drawings from these accompanying drawings without creative efforts.

FIG. 1 is a schematic plan view of a display panel according to an embodiment of the present disclosure.

FIG. 2 is a schematic diagram of a cross-sectional structure of a display panel according to an embodiment of the present disclosure.

FIG. 3 is a schematic diagram of a shape of a light-emitting subpixel according to an embodiment of the present disclosure.

FIG. 4 is a schematic diagram of a dummy through hole according to an embodiment of the present disclosure.

FIG. 5 is a schematic diagram of another dummy through hole according to an embodiment of the present disclosure.

FIG. 6 is a schematic diagram of still another dummy through hole according to an embodiment of the present disclosure.

FIG. 7 is a flowchart of a method for manufacturing a display panel according to an embodiment of the present disclosure.

### DETAILED DESCRIPTION OF PREFERRED EMBODIMENTS

The following clearly and completely describes the technical solutions in embodiments of the present disclosure with reference to the accompanying drawings in the embodiments of the present disclosure. Apparently, the described embodiments are only some embodiments rather than all the embodiments of the present disclosure. All other embodiments obtained by a person skilled in the art based on the embodiments of the present disclosure without creative efforts shall fall within the protection scope of the present disclosure.

In the description of the present disclosure, it should be understood that orientation or position relationships indicated by the terms, such as “center”, “longitudinal”, “transverse”, “length”, “width”, “thickness”, “on”, “below”, “front”, “back”, “left”, “right”, “vertical”, “horizontal”, “top”, “bottom”, “inside”, “outside”, “clockwise”, and “anticlockwise” are based on orientation or position relationships shown in the accompanying drawings, and are used only for ease and brevity of illustration and description, rather than indicating or implying that the mentioned apparatus or component need to have a particular orientation or need to be constructed and operated in a particular orientation. Therefore, such terms should not be construed as a limitation on the present disclosure. In addition, the terms “first” and “second” are used for the purpose of description only, and should not be understood as indicating or implying relative importance or implicitly indicating a quantity of indicated technical features. Therefore, a feature restricted by “first” or “second” may explicitly indicate or implicitly include one or more such features. In the descriptions of the present disclosure, “a plurality of” means two or more, unless otherwise definitely and specifically limited.

Many different implementations or examples are provided below to implement different structures of the present disclosure. To simplify the disclosure of the present disclosure, the following describes components and settings of particular examples. Certainly, the components and settings are merely examples, and are not intended to limit the present disclosure. In addition, in the present disclosure, reference numbers and/or reference letters may be repeated in different examples. Such repetition is intended to simplify and clarify the present disclosure, and does not indicate a relationship between various implementations and/or settings that are discussed. In addition, the present disclosure provides examples of various specific processes and materials, but a person skilled in the art may be aware of the applicability of another process and/or the use of another material.

The technical solutions of the present disclosure are described now with reference to specific embodiments.

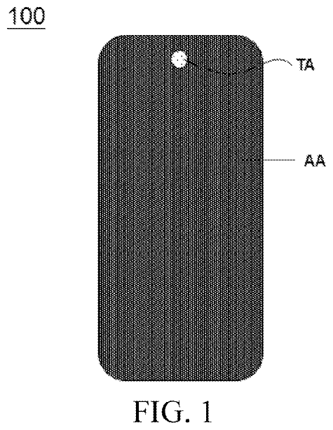

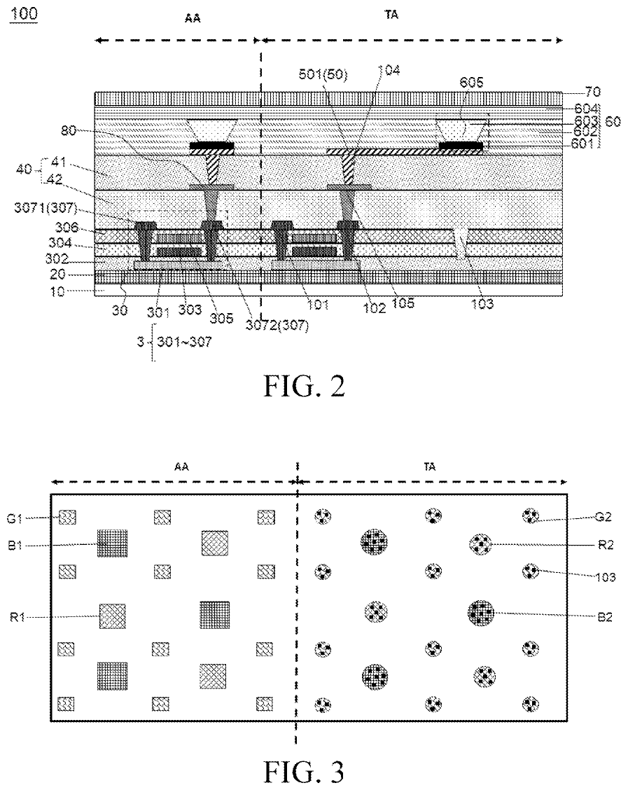

As shown in FIGS. 1 and 2, the present disclosure provides a display panel 100, and more specifically, an organic light-emitting diode (OLED) display panel. A first display region AA and a second display region TA are defined on the display panel 100. In the present embodiment of the present disclosure, the first display region AA may be a normal display region, and the second display region TA may be a camera under panel (CUP) region. The second display region TA of the CUP region has a large-area transparent region, to provide sufficient light transmittance for a camera to photograph an image in a photographing mode state.

In an embodiment, the display panel 100 includes a substrate 10, a driving device layer 3, and a light-emitting device layer 60.

The substrate 10 may be a glass substrate or a flexible substrate, which is not particularly limited in the present disclosure.

The driving device layer 3 is disposed on the substrate 10 and includes a plurality of thin film transistors (TFTs) 30; and the light-emitting device layer 60 is disposed on the driving device layer 3 and includes a plurality of light-emitting subpixels 605 arranged in an array.

Further, the display panel 100 is further provided with a buffer layer 20 between the driving device layer 3 and the substrate 10.

In the second display region TA, the driving device layer 3 is further provided with a dummy through hole 103 located within an orthographic projection range of at least one of the light-emitting subpixels 605 on the substrate 10, and the dummy through hole 103 and the at least one light-emitting subpixel 605 are insulated from each other.

Generally, in the art, a through hole is provided and is filled with a conductive material, so that an upper-layer metal layer and a lower-layer metal layer may be electrically connected, to conduct an electronic component. However, the dummy through hole in the present disclosure is filled with a non-conductive material, and further has a characteristic of insulating from the electronic component.

The non-conductive material may include an organic planarization layer material, and the organic planarization layer material has excellent flatness and light transmittance.

Therefore, provided with the dummy through hole 103, the driving device layer 3 may also have a uniform hole-opening density in the second display region TA while maintaining flatness and a large-area transparent region, to uniformly remove impurity elements, such as hydrogen in an annealing process, and electrical uniformity between the TFTs 30 in the second display region TA is ensured, thereby alleviating non-uniform display of the display panel 100. In addition, the dummy through hole 103 and the at least one light-emitting subpixel 605 are insulated from each other, so that the dummy through hole 103 cannot affect the display effect of the second display region TA while improving the electrical properties of the second display region TA.

Preferably, the dummy through hole 103 is located within an orthographic projection range of each of the light-emitting subpixels 605 on the substrate 10 to make the hole-opening density more uniform.

In an embodiment of the present disclosure, a plurality of dummy through holes 103 may have a same size or different sizes, as long as the second display region TA has a uniform hole-opening density.

Further, in the second display region TA, the TFTs 30 are disposed at an edge of the second display region TA close to the first display region AA. It may be understood that, in the second display region TA, the TFTs 30 are disposed at the edge of the second display region TA close to the first display region AA, so that the TFTs 30 and lines (such as gate lines or data lines) connecting the TFTs 30 may occupy only a small part of an area of the second display region TA, and furthermore the second display region TA may further have a larger-area transparent region, to provide sufficient light transmittance for a camera to photograph an image in a photographing mode state.

In an embodiment of the present disclosure, the TFT 30 is disposed at a same layer with the dummy through hole 103.

Further, in the first display region AA, the driving device layer 3 is provided with a plurality of through holes corresponding to the light-emitting subpixels 605, and the through holes are electrically connected to the light-emitting subpixels 605,
wherein a density of the dummy through holes 103 in the second display region TA is equal to a density of the through holes in the first display region AA.

Specifically, the TFT 30 includes an active layer 301, a first insulating layer 302, a first metal layer 303, a second insulating layer 306, and a second metal layer 307. The active layer 301 is disposed on the substrate 10; the first insulating layer 302 covers the active layer 301; the first metal layer 303 is disposed on the first insulating layer 302 to form a first gate; the second insulating layer 306 is disposed on the first metal layer 303; and the second metal layer 307 is disposed on the second insulating layer 306 and is patterned to form a source 3071 and a drain 3072, wherein the source 3071 and the drain 3072 are electrically connected to the active layer 301 respectively through a first through hole 101 and a second through hole 102 that runs through the first insulating layer 302 and the second insulating layer 306. In the first display region AA, the through holes corresponding to the light-emitting subpixels 605 includes the first through hole 101 and the second through hole 102.

The dummy through hole 103 is disposed at a same layer with the first through hole 101 and the second through hole 102. The dummy through hole 103 is disposed at the same layer with the first through hole 101 and the second through hole 102, so that the dummy through hole 103 may be simultaneously formed with the first through hole 101 and the second through hole 102 in a same hole-opening process without an additional hole-opening process, and further no additional preparation process is required when the dummy through hole 103 is formed. Therefore, the preparation procedure can be simplified and the preparation costs can be reduced.

In addition, in the present disclosure, a density of the dummy through holes 103 in the second display region TA is set to be equal to a density of the through holes in the first display region AA, thereby also ensuring that the first display region AA and the second display region TA have a uniform hole-opening density while ensuring that the second display region TA has a uniform hole-opening density, and further improving the overall display uniformity of the display panel 100.

In another embodiment of the present disclosure, the TFT 30 further includes a third insulating layer 304 and a third metal layer 305. The third insulating layer 304 is disposed between the first insulating layer 302 and the second insulating layer 306 and covers the first metal layer 303. The third metal layer 305 is disposed on the third insulating layer 304 and is covered by the second insulating layer 306. The third metal layer 305 is formed with a second gate, and the second gate and the first gate may form a capacitance to further prevent electric leakage of the TFT 30.

In the present embodiment, the source 3071 and the drain 3072 are electrically connected to the active layer 301 respectively through the first through hole 101 and the second through hole 102 that run through the first insulating layer 302, the third insulating layer 304, and the second insulating layer 306. The dummy through hole 103 may also be formed by running through the first insulating layer 302, the third insulating layer 304, and the second insulating layer 306, so that the dummy through hole 103 may be simultaneously formed with the first through hole 101 and the second through hole 102 in a same hole-opening process without an additional hole-opening process, and further no additional preparation process is required when the dummy through hole 103 is formed. Therefore, the preparation procedure can be simplified and the preparation costs can be reduced.

Further, the display panel 100 further includes an organic planarization layer 40, and the organic planarization layer 40 is disposed between the driving device layer 3 and the light-emitting device layer 60. The dummy through hole 103 may be directly filled with the organic planarization layer 40. The additional preparation process can be omitted by directly filling the dummy through hole 103 with the organic planarization layer 40, and therefore the preparation procedure can be simplified and the preparation costs can be reduced.

It may be understood that, the driving device layer 3 includes the active layer 301, the first insulating layer 302, the first metal layer 303, the second insulating layer 306, the second metal layer 307, the third insulating layer 304, and the third metal layer 305. The first insulating layer 302, the third insulating layer 304, and the second insulating layer 306 may be inorganic insulating layers, and the second insulating layer 306 may be used for improving stress and supplementing a hydrogen source, to further make up TFT channel defects and improve the electrical properties.

Further, the display panel 100 further includes a transparent metal layer 50. The transparent metal layer 50 is disposed between the organic planarization layer 40 and the light-emitting device layer 60, and is electrically connected to the drain 3072 through the third through hole 104 that runs through the organic planarization layer 40. The transparent metal layer 50 may be made of indium tin oxide (ITO).

It should be noted that, in the second display region TA, the transparent metal layer 50 is patterned to form a transparent metal line 501. The transparent metal line 501 extends from a position corresponding to a position below the light-emitting subpixels 605 to a position corresponding to a position above the TFTs 30 at the edge of the second display region TA, and the TFTs 30 are electrically connected to the light-emitting subpixels 605 through the transparent metal line 501.

In the second display region TA, in the present disclosure, the transparent metal line 501 is electrically connected to the light-emitting subpixels 605 and the TFTs 30 located at the edge of the second display region TA, so that an electrical connection between the light-emitting subpixels 605 and the TFTs 30 is implemented, and the second display region TA further maintains a larger-area transparent region, to provide sufficient light transmittance for a camera to photograph an image in a photographing mode state.

In another embodiment, the organic planarization layer 40 includes a first organic planarization layer 41 and a second organic planarization layer 42. The second organic planarization layer 42 is disposed on the second insulating layer 306, the first organic planarization layer 41 is disposed on the second organic planarization layer 42, and the display panel 100 further includes a fourth metal layer 80 disposed between the first organic planarization layer 41 and the second organic planarization layer 42. The fourth metal layer 80 may be made of indium zinc oxide (IZO).

In the present embodiment, the fourth metal layer 80 is electrically connected to the transparent metal layer 50 and the drain 3072. Specifically, the transparent metal layer 50 is electrically connected to the fourth metal layer 80 through the third through hole 104, and the fourth metal layer 80 is electrically connected to the drain 3072 through the fourth through hole 105. The fourth metal layer 80 is electrically connected to the transparent metal layer 50 and the drain 3072 to further reduce voltage drop and improve the display effect.

Further, the light-emitting device layer 60 may further include an anode 601, a pixel definition layer 602, a light-emitting material layer 603, and a cathode 604. The light-emitting subpixel 605 is located within a hole-opening region in which the pixel definition layer 602 is disposed and includes the anode 601 and the light-emitting material layer 603, and the cathode 604 covers the light-emitting subpixel 605 and the pixel definition layer 602. The anode 601 may be made of ITO/Ag/ITO. In the first display region AA, the light-emitting subpixel 605 includes a first red subpixel unit R1, a first green subpixel unit G1, and a first blue subpixel unit B1, wherein the first red subpixel unit R1 is configured to emit red light, the first green subpixel unit G1 is configured to emit green light, and the first blue subpixel unit B1 is configured to emit blue light.

In the second display region TA, the light-emitting subpixel 605 includes a second red subpixel unit R2, a second green subpixel unit G2, and a second blue subpixel unit B2, wherein the second red subpixel unit R2 is configured to emit red light, the second green subpixel unit G2 is configured to emit green light, and the second blue subpixel unit B2 is configured to emit blue light.

In an embodiment, as shown in FIG. 3, in the first display region AA, the first red subpixel unit R1, the first green subpixel unit G1, and the first blue subpixel unit B1 are all rectangular, a light-emitting area of the first blue subpixel unit B1 is greater than light-emitting areas of the first red subpixel unit R1 and the first green subpixel unit G1, and the light-emitting area of the first red subpixel unit R1 is greater than the light-emitting area of the first green subpixel unit G1.

It should be noted that, shapes of the first red subpixel unit R1, the first green subpixel unit G1, and the first blue subpixel unit B1 are not limited to rectangles, and may further be correspondingly set according to a shape of the first display region AA. In addition, because light-emitting efficiency of the first blue subpixel unit B1 is poor but light-emitting efficiency of the first green subpixel unit G1 is better, the light-emitting area of the first blue subpixel unit B1 may be set to the largest, and the light-emitting area of the first green subpixel unit G1 may be set to the smallest, so that the first red subpixel unit R1, the first green subpixel unit G1, and the first blue subpixel unit B1 have more uniform luminance.

In the second display region TA, the second red subpixel unit R2, the second green subpixel unit G2, and the second blue subpixel unit B2 are all circular, a light-emitting area of the second blue subpixel unit B2 is greater than light-emitting areas of the second red subpixel unit R2 and the second green subpixel unit G2, and the light-emitting area of the second red subpixel unit R2 is greater than the light-emitting area of the second green subpixel unit G2.

It should be noted that, shapes of the second red subpixel unit R2, the second green subpixel unit G2, and the second blue subpixel unit B2 are limited to circles, and therefore the areas of the second red subpixel unit R2, the second green subpixel unit G2, and the second blue subpixel unit B2 are minimized to further increase the light transmittance, so that the second display region TA has a larger-area transparent region, to provide sufficient light transmittance for a camera to photograph an image in a photographing mode state. In addition, because light-emitting efficiency of the second blue subpixel unit B2 is poor but light-emitting efficiency of the second green subpixel unit G2 is better, the light-emitting area of the second blue subpixel unit B2 may be set to the largest, and the light-emitting area of the second green subpixel unit G2 may be set to the smallest, so that the second red subpixel unit R2, the second green subpixel unit G2, and the second blue subpixel unit B2 have more uniform luminance.

For the shape and size design of the light-emitting subpixel 605 in the second display region TA and the design of the line for connecting the light-emitting subpixel and the TFT 30, reference may be specifically made to related patent documents CN112103329A and CN112259596A, and details are not described herein again.

In an embodiment of the present disclosure, in the second display region TA, a quantity of the dummy through holes 103 located within the orthographic projection range of the at least one light-emitting subpixel 605 on the substrate 10 is greater than or equal to 1. A shape of the dummy through hole 103 includes at least one of a rectangle or a circle.

In an embodiment of the present disclosure, the light-emitting subpixels 605 have different sizes, and the quantity of the dummy through holes 103 is proportional to the sizes of the light-emitting subpixels 605.

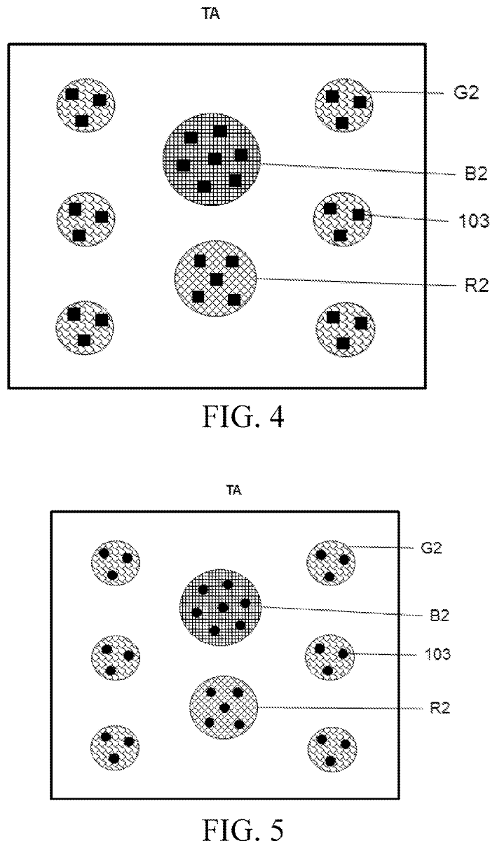

Specifically, the size of the second blue subpixel unit B2 is greater that of the second red subpixel unit R2, and the size of the second red subpixel unit R2 is greater than that of the second green subpixel unit G2. As shown in FIG. 4, a quantity of dummy through holes 103 corresponding to the second red subpixel unit R2 is 5, a quantity of dummy through holes 103 corresponding to the second green subpixel unit G2 is 3, a quantity of dummy through holes 103 corresponding to the second blue subpixel unit B2 is 7, and the shape of the dummy through hole 103 is a rectangle.

In the present disclosure, the quantity of the dummy through holes 103 is set to be proportional to the sizes of the light-emitting subpixels 605, to further ensure that the second display region TA has a uniform hole-opening density.

In another embodiment of the present disclosure, as shown in FIG. 5, a difference from FIG. 4 is only in that the shape of the dummy through hole 103 is a circle.

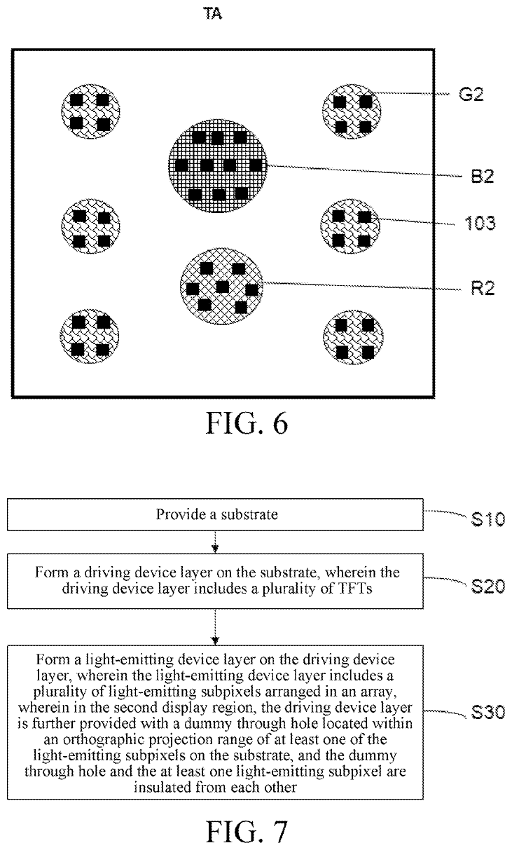

In still another embodiment of the present disclosure, as shown in FIG. 6, a difference from FIG. 4 is only in that a quantity of dummy through holes 103 corresponding to the second red subpixel unit R2 is 7, a quantity of dummy through holes 103 corresponding to the second green subpixel unit G2 is 4, a quantity of dummy through holes 103 corresponding to the second blue subpixel unit B2 is 10.

It may be understood that, the quantity of the dummy through holes 103 within the orthographic projection range of the at least one light-emitting subpixel 605 on the substrate 10 is not limited, and may be set according to a specific requirement, as long as it is ensured that the second display region TA has a uniform hole-opening density, to uniformly remove impurity elements, such as hydrogen in an annealing process. Therefore, the electrical uniformity between the TFTs 30 in the second display region TA can be ensured, thereby alleviating the non-uniform display of the display panel 100.

In addition, the shapes of the dummy through hole 103 may include a rectangle or a circle, and may be set according to a specific requirement.

Further, the display panel 100 further includes a thin film encapsulation layer 70, and the thin film encapsulation layer 70 is configured to isolate external water or oxygen, to prevent the display panel 100 from failing.

As shown in FIG. 7, the present disclosure further provides a method for manufacturing a display panel 100. The preparation method includes the following steps:
S10. Provide a substrate 10.
S20. Form a driving device layer 3 on the substrate 10, wherein the driving device layer 3 includes a plurality of TFTs 30.
S30. Form a light-emitting device layer 60 on the driving device layer 3, wherein the light-emitting device layer 60 includes a plurality of light-emitting subpixels 605 arranged in an array, wherein in the second display region TA, the driving device layer 3 is further provided with a dummy through hole 103 located within an orthographic projection range of at least one of the light-emitting subpixels 605 on the substrate 10, and the dummy through hole 103 and the at least one light-emitting subpixel 605 are insulated from each other.

Generally, in the art, a through hole is provided and is filled with a conductive material, so that an upper-layer metal layer and a lower-layer metal layer may be electrically connected, to conduct an electronic component. However, the dummy through hole in the present disclosure is filled with a non-conductive material, and further has a characteristic of insulating from the electronic component.

The non-conductive material may include an organic planarization layer material, and the organic planarization layer material has excellent flatness and light transmittance.

In the method for manufacturing the display panel according to the present disclosure, provided with the dummy through hole 103, the driving device layer 3 may also have a uniform hole-opening density in the second display region TA while maintaining flatness and a large-area transparent region, to uniformly remove impurity elements, such as hydrogen in an annealing process, and electrical uniformity between the TFTs 30 in the second display region TA is ensured, thereby alleviating non-uniform display of the display panel 100. In addition, the dummy through hole 103 and the at least one light-emitting subpixel 605 are insulated from each other, so that the dummy through hole 103 cannot affect the display effect of the second display region TA while improving the electrical properties of the second display region TA.

The preparation method further includes S11: forming a buffer layer 20 on the substrate 10.

The step S20 further includes the following steps:
S201. Sequentially dispose an active layer 301, a first insulating layer 302, a first metal layer 303, a third insulating layer 304, a third metal layer 305, and a second insulating layer 306 on the buffer layer 20.
S202. Provide a first through hole 101, a second through hole 102, and a dummy through hole 103 located in the second display region TA that run through the first insulating layer 302, the third insulating layer 304, and the second insulating layer 306.
S203. Form a second metal layer 307 on the second insulating layer 306, wherein the second metal layer 307 is patterned to form a source 3071 and a drain 3072, and the source 3071 and the drain 3072 are electrically connected to the active layer 301 respectively through the first through hole 101 and the second through hole 102.

Therefore, the dummy through hole 103 may be simultaneously formed with the first through hole 101 and the second through hole 102 in a same hole-opening process without an additional hole-opening process, and further no additional preparation process is required when the dummy through hole 103 is formed. Therefore, the preparation procedure can be simplified and the preparation costs can be reduced.

After step S203, the preparation method further includes S21: forming an organic planarization layer 40 on the second metal layer 307.

The dummy through hole 103 may be directly filled with the organic planarization layer 40. The additional preparation process can be omitted by directly filling the dummy through hole 103 with the organic planarization layer 40, and therefore the preparation procedure can be simplified and the preparation costs can be reduced.

After step S21, the preparation method further includes S22: forming a transparent metal layer 50 on the organic planarization layer 40, wherein in the second display region TA, the transparent metal layer 50 is patterned to form a transparent metal line 501. The transparent metal line 501 extends from a position corresponding to a position below the light-emitting subpixels 605 to a position corresponding to a position above the TFTs 30 at the edge of the second display region TA, and the TFTs 30 are electrically connected to the light-emitting subpixels 605 through the transparent metal line 501.

In the second display region TA, in the present disclosure, the transparent metal line 501 is electrically connected to the light-emitting subpixels 605 and the TFTs 30 located at the edge of the second display region TA, so that an electrical connection between the light-emitting subpixels 605 and the TFTs 30 is implemented, and the second display region TA further maintains a larger-area transparent region, to provide sufficient light transmittance for a camera to photograph an image in a photographing mode state.

After step S30, the preparation method further includes S40: forming a thin film encapsulation layer 70 on the light-emitting device layer 60.

For a detailed description of each layer, refer to the above display panel 100, and details are not described in this preparation method again.

In the above embodiment, the descriptions of the embodiments have respective focuses, and for a part that is not described in detail in one embodiment, reference may be made to the related descriptions of other embodiments.

The embodiments of the present disclosure are described above in detail. Although the principles and implementations of the present disclosure are described using specific examples in this specification, the descriptions of the above embodiments are merely intended to help understand the technical solutions and the core idea of the present disclosure. It should be understood by persons of ordinary skill in the art that modifications can be made to the technical solutions recorded in the above embodiments, or equivalent replacements can be made to some technical features in the technical solutions, as long as such modifications or replacements do not cause the essence of corresponding technical solutions to depart from the scope of the technical solutions of the embodiments of the present disclosure.

What is claimed is:

1. A display panel, wherein a first display region and a second display region are defined on the display panel, and the display panel comprises:
a substrate;
a driving device layer disposed on the substrate and comprising a plurality of thin film transistors (TFTs); and
a light-emitting device layer disposed on the driving device layer and comprising a plurality of light-emitting subpixels arranged in an array,
wherein in the second display region, the driving device layer is further provided with a dummy through hole located within an orthographic projection range of at least one of the light-emitting subpixels on the substrate, and the dummy through hole and the at least one light-emitting subpixel are insulated from each other.

2. The display panel as claimed in claim 1, wherein in the second display region, the TFT is disposed at an edge of the second display region close to the first display region.

3. The display panel as claimed in claim 1, wherein the TFT is disposed at a same layer with the dummy through hole.

4. The display panel as claimed in claim 3, wherein the TFT comprises:
an active layer disposed on the substrate;
a first insulating layer covering the active layer;
a first metal layer disposed on the first insulating layer;
a second insulating layer disposed on the first metal layer; and
a second metal layer disposed on the second insulating layer and patterned to form a source and a drain, wherein the source and the drain are electrically connected to the active layer respectively through a first through hole and a second through hole both running through the first insulating layer and the second insulating layer, and
wherein the dummy through hole is disposed at a same layer with the first through hole and the second through hole.

5. The display panel as claimed in claim 1, wherein a quantity of the dummy through holes located within the orthographic projection range of the at least one light-emitting subpixel on the substrate is greater than or equal to 1.

6. The display panel as claimed in claim 1, wherein a shape of the dummy through hole comprises at least one of a rectangle or a circle.

7. The display panel as claimed in claim 5, wherein the light-emitting subpixels have different sizes, and the quantity of the dummy through holes is proportional to the sizes of the light-emitting subpixels.

8. The display panel as claimed in claim 1, wherein in the first display region, the driving device layer is provided with a plurality of through holes corresponding to the light-emitting subpixels, and the through holes are electrically connected to the light-emitting subpixels, and
wherein a density of the dummy through holes in the second display region is equal to a density of the through holes in the first display region.

9. The display panel as claimed in claim 4, wherein the display panel further comprises an organic planarization layer, wherein the organic planarization layer is disposed between the driving device layer and the light-emitting device layer, and the organic planarization layer fills the dummy through hole running through the first insulating layer and the second insulating layer.

10. The display panel as claimed in claim 1, wherein the dummy through hole is filled with a non-conductive material.

11. A method for manufacturing a display panel, wherein a first display region and a second display region are defined on the display panel, and the preparation method comprises steps of:
providing a substrate;
forming a driving device layer on the substrate, wherein the driving device layer comprises a plurality of thin film transistors (TFTs); and
forming a light-emitting device layer on the driving device layer, wherein the light-emitting device layer comprises a plurality of light-emitting subpixels arranged in an array,
wherein in the second display region, the driving device layer is further provided with a dummy through hole located within an orthographic projection range of at least one of the light-emitting subpixels on the substrate, and the dummy through hole and the at least one light-emitting subpixel are insulated from each other.

12. The method for manufacturing the display panel as claimed in claim 11, wherein in the second display region, the TFT is disposed at an edge of the second display region close to the first display region.

13. The method for manufacturing the display panel as claimed in claim 11, wherein the TFT is disposed at a same layer with the dummy through hole.

14. The method for manufacturing the display panel as claimed in claim 11, wherein the step of forming the driving device layer on the substrate comprises:
sequentially disposing an active layer, a first insulating layer, a first metal layer, a second insulating layer, and a second metal layer on the substrate, wherein the second metal layer is patterned to form a source and a drain; and
providing a first through hole and a second through hole both running through the first insulating layer and the second insulating layer and the dummy through hole located in the second display region,
wherein the source and the drain are electrically connected to the active layer respectively through the first through hole and the second through hole.

15. The method for manufacturing the display panel as claimed in claim 14, wherein the step of forming the driving device layer on the substrate further comprises: forming an organic planarization layer on the second metal layer.

16. The method for manufacturing the display panel as claimed in claim 11, wherein a quantity of the dummy through holes located within the orthographic projection range of the at least one light-emitting subpixel on the substrate is greater than or equal to 1.

17. The method for manufacturing the display panel as claimed in claim 16, wherein the light-emitting subpixels have different sizes, and the quantity of the dummy through holes is proportional to the sizes of the light-emitting subpixels.

18. The method for manufacturing the display panel as claimed in claim 11, wherein in the first display region, the driving device layer is provided with a plurality of through holes corresponding to the light-emitting subpixels, and the through holes are electrically connected to the light-emitting subpixels, and
wherein a density of the dummy through holes in the second display region is equal to a density of the through holes in the first display region.

19. The method for manufacturing the display panel as claimed in claim 15, wherein the organic planarization layer fills the dummy through hole running through the first insulating layer and the second insulating layer.

20. The method for manufacturing the display panel as claimed in claim 11, wherein the dummy through hole is filled with a non-conductive material.
